(19) United States
(12) Patent Application Publication
(10) Pub. No.: US 2023/0253990 A1
(43) Pub. Date: Aug. 10, 2023

(54) MULTI-BAND INPUT STAGE OF RECEIVER WITH SELECTABLE THIRD HARMONIC FILTER

(71) Applicant: QUALCOMM Incorporated, San Diego, CA (US)

(72) Inventors: Rahul SINGH, San Diego, CA (US); Bo YANG, San Diego, CA (US)

(21) Appl. No.: 17/669,178

(22) Filed: Feb. 10, 2022

(51) Int. Cl. H04B 1/00; H04B 1/10; H03H 7/46; H03F 3/19

(52) U.S. Cl. CPC H04B 1/006; H04B 1/0089; H04B 1/1036; H03H 7/465; H03F 3/19; H03H 2250/00

(57) ABSTRACT

An aspect of the disclosure relates to a receiver, including: a low noise amplifier (LNA); and an input stage coupled to the LNA, wherein the input stage is configured to provide a first passband for a first signal across at least a portion of a first frequency band and a notch to substantially reject a second signal within the first frequency band or a second frequency band in accordance with a first mode of operation, and a second passband for the second signal across the second frequency band in accordance with a second mode of operation. In the first mode, the input stage includes a parallel L-C resonance frequency and an L-match impedance matching circuit. In the second mode, the input stage includes a modified bridge T-coil impedance matching circuit with substantially no electromagnetic coupling between the inductors of the circuit.

### FIELD

Aspects of the present disclosure relate generally to receivers, and in particular, to a multi-band input stage of a receiver with selectable third harmonic filter.

### BACKGROUND

A receiver typically includes an input stage followed by a low noise amplifier (LNA) and a frequency downconverting mixer. The input stage may be configured to receive signals across multiple frequency bands. The input stage should provide passbands across the multiple frequency bands, good impedance matching across the multiple frequency bands, programmable attenuation without degrading the passbands and impedance matching if different signal power levels are seen by the input stage, and third harmonic suppression filtering if a leaked signal has a frequency three (3) times the frequency of the target received signal (or other harmonics).

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to a receiver. The receiver includes a low noise amplifier (LNA); and an input stage coupled to the LNA. The input stage, in turn, includes a first inductor coupled between a first node and a second node; a second inductor coupled between the second node and a third node; a first variable capacitor coupled between the first node and the third node; a variable resistor coupled between the third node and a reference potential rail; a first switching device coupled between the second node and a fourth node; a second switching device coupled between the third node and the fourth node; and a second variable capacitor coupled between the fourth node and the reference potential rail.

Another aspect of the disclosure relates to a receiver. The receiver includes a low noise amplifier (LNA); and an input stage coupled to the LNA, wherein the input stage is configured to provide a first passband for a first signal across at least a portion of a first frequency band and a notch to substantially reject a second signal within the first frequency band or a second frequency band in accordance with a first mode of operation, and a second passband for the second signal across the second frequency band in accordance with a second mode of operation.

Another aspect of the disclosure relates to a method of processing first and second signals. The method includes providing a passband for the first signal across at least a portion of a first frequency band and a notch to substantially reject a second signal within the first frequency band or a second frequency band in accordance with a first mode of operation; and providing a passband for the second signal across the second frequency band in accordance with a second mode of operation.

Another aspect of the disclosure relates to a transmitter system. The transmitter system includes a first amplifier configured to generate a first signal; a second amplifier configured to generate a second signal; and a feedback receiver, including: a low noise amplifier (LNA); and an input stage coupled to the LNA, wherein the input stage is configured to provide a first passband for the first signal across at least a portion of a first frequency band and a notch to substantially reject the second signal within the first frequency band or a second frequency band in accordance with a first mode of operation, and a second passband for the second signal across the second frequency band in accordance with a second mode of operation.

Another aspect of the disclosure relates to an apparatus for processing first and second signals. The apparatus includes means for providing a first passband for the first signal across at least a portion of a first frequency band and a notch to substantially reject a second signal within the first frequency band or a second frequency band in accordance with a first mode of operation; and means for providing a second passband for the second signal across the second frequency band in accordance with a second mode of operation.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1A illustrates a block diagram of an example transmitter system in accordance with an aspect of the disclosure.

FIG. 1B illustrates a graph depicting an example frequency spectrum of first and second transmit signals of the transmitter system of FIG. 1A in accordance with another aspect of the disclosure.

FIG. 1C illustrates a graph depicting an example frequency spectrum of a down converted feedback signal of the transmitter system of FIG. 1A in accordance with another aspect of the disclosure.

FIG. 1D illustrates a graph depicting another example frequency spectrum of first and second transmit signals of the transmitter system of FIG. 1A in accordance with another aspect of the disclosure.

FIG. 1E illustrates a graph depicting another example frequency spectrum of a down converted feedback signal of the transmitter system of FIG. 1A in accordance with another aspect of the disclosure.

FIG. 2A illustrates a block diagram of an example receiver in accordance with another aspect of the disclosure.

FIG. 2B illustrates a graph depicting an example S21 frequency response of an example input stage of the receiver of FIG. 2A in accordance with another aspect of the disclosure.

FIG. 2C illustrates a graph depicting another example S21 frequency response of the input stage of the receiver of FIG. 2A in accordance with another aspect of the disclosure.

FIG. 3A illustrates a schematic diagram of an example receiver input stage in accordance with another aspect of the disclosure.

FIG. 3B illustrates a schematic diagram of an example equivalent circuit of the receiver input stage of FIG. 3A in a first mode of operation in accordance with another aspect of the disclosure.

FIG. 3C illustrates a schematic diagram of an example equivalent circuit of the receiver input stage of FIG. 3A in a second mode of operation in accordance with another aspect of the disclosure.

FIG. 4 illustrates a schematic diagram of another example receiver input stage in accordance with another aspect of the disclosure.

FIG. 5 illustrates plan and cross-sectional views of an example inductive component used in an example receiver input stage in accordance with another aspect of the disclosure.

FIG. 6 illustrates a schematic diagram of another example receiver input stage in accordance with another aspect of the disclosure.

FIG. 7 illustrates plan and cross-sectional views of another example inductive component used in an example receiver input stage in accordance with another aspect of the disclosure.

FIG. 8 illustrates a flow diagram of an example method of processing first and second signals in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

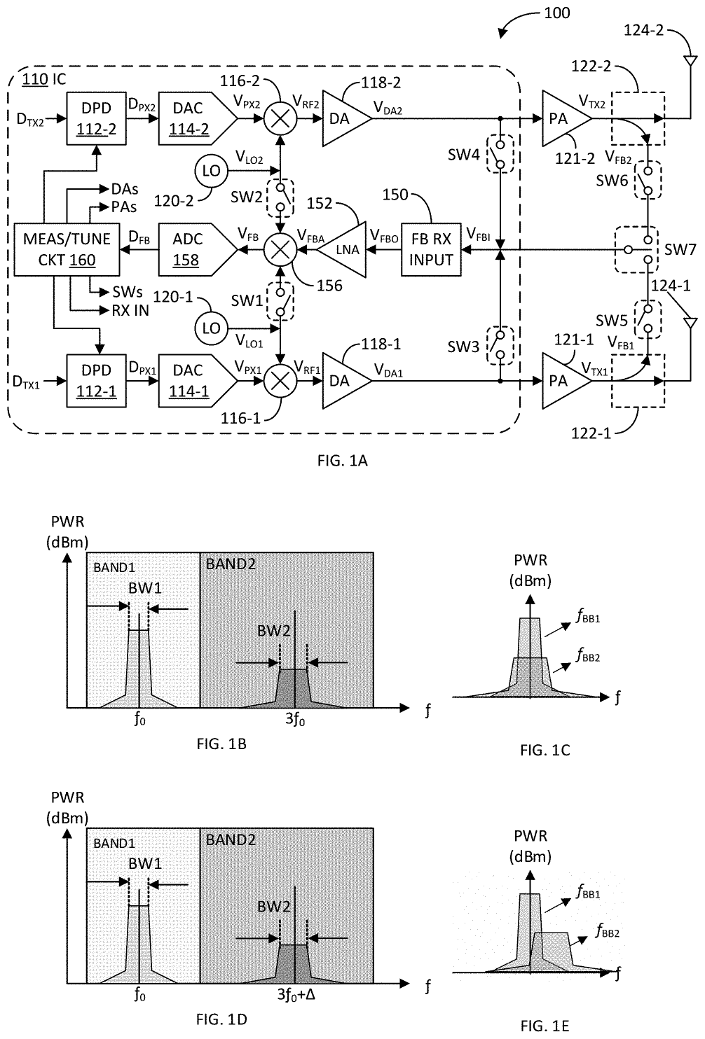

FIG. 1A illustrates a block diagram of an example transmitter system 100 in accordance with an aspect of the disclosure. As discussed further herein, the transmitter system 100 may be configured to transmit signals in accordance with carrier aggregation, such as uplink carrier aggregation (ULCA). In carrier aggregation, a set of carriers may be used to transmit data simultaneously to one or more remote wireless devices. Further, the transmitter system 100 includes a feedback receiver to measure and tune a set of transmit chains used to transmit the data-modulated carriers in accordance with carrier aggregation.

In particular, the transmitter system 100 includes an integrated circuit (IC) 110, which may be implemented as a system on chip (SOC). In this example, the IC 110 includes a first transmit chain including a first digital predistortion (DPD) circuit 112-1, a first digital-to-analog converter (DAC) 114-1, a first local oscillator (LO) 120-1, a first frequency up converting mixer 116-1, and a first driver amplifier (DA) 118-1 (may also be referred to as a pre-amplifier). Similarly, the IC 110 includes a second transmit chain including a second DPD circuit 112-2, a second DAC 114-2, a second LO 120-2, a second frequency up converting mixer 116-2, and a second DA 118-2. Although, in this example, the IC 110 is shown to have two (2) transmit chains, it shall be understood that the IC 110 may include more than two (2) transmit chains. The IC 110 may further include a feedback receiver (FB RX) including an input stage 150, a low noise amplifier (LNA) 152, a frequency down converting mixer 156, an analog-to-digital converter (ADC) 158, a measurement/tuning circuit 160, and a first set of switching devices SW1-SW4. The measurement/tuning circuit 160 may be any processor-based circuit (e.g., microprocessor, microcontroller, field programmable gate array, etc.), which may include an associated memory with instructions, and/or part of a firmware, etc.

Further, in accordance with this example, the transmitter system 100 may further include components external to the IC 110, such as a first power amplifier (PA) 121-1, first directional coupler 122-1, and first antenna (or antenna array) 124-1 associated with the first transmit chain. Similarly, external to the IC 110, the transmitter system 100 includes a second PA 121-2, second directional coupler 122-2, and second antenna (or antenna array) 124-2 associated with the second transmit chain. Additionally, external to the IC 110, the transmitter system 100 includes a second set of switching devices SW5 to SW7.

It shall be understood that the division between what components are in the IC 110 and components external to the IC 110 may vary depending on design factors (and that certain components of the IC 110 may be split among different ICs—such as the DPD circuit 112-2 that may be in a different IC than the mixer 116-2 etc.). It shall also be understood that the transmitter system 100 may be implemented with discrete components (in lieu of the IC 110) or with integrated components entirely within the IC 110.

With reference to the first transmit chain, a first digital data signal D_{TX1} is provided to an input of the first DPD circuit 112-1. The first DPD circuit 112-1 applies predistortion to the first digital data signal D_{TX1} based on control signals from the measurement/tuning circuit 160 to generate a first predistorted digital signal D_{PX1}. The first DAC 114-1 may receive the first predistorted digital signal D_{PX1} directly or via one or more components, and convert the first predistorted digital signal D_{PX1} into a first predistorted analog signal V_{PX1}. As mentioned, one or more intervening components between the first DPD circuit 112-1 and the first DAC 114-1 may include a data scrambler, an error correction code (ECC) circuit, a modulator, and/or other circuit(s). The first mixer 116-1 mixes the first predistorted analog signal V_{PX1} with a first LO signal V_{LO1} generated by the first LO 120-1 (upconverts the first predistorted analog signal V_{PX1}) to generate a first radio frequency (RF) signal V_{RF1}. It should be appreciated that in some systems the first mixer 116-1 mixes the first predistorted analog signal V_{PX1} with a first LO signal V_{LO1} generated by the first LO 120-1 (upconverts the first predistorted analog signal V_{PX1}) to generate a first intermediate frequency (IF) that may be then upconverted to an RF frequency at a later transmitter stage. It shall be understood that one or more filters may be associated with the first mixer 116-1 to substantially remove or suppress unwanted signal components from the first RF signal V_{RF1}.

The first DA 118-1 amplifies the first RF signal V_{RF1} to generate a first pre-amplified signal V_{DA1} based on control signals generated by the measurement/tuning circuit 160. The first PA 121-1 amplifies the first pre-amplified signal V_{DA1} based on control signals generated by the measurement/tuning circuit 160 to generate a first transmit signal V_{TX1}. The first transmit signal V_{TX1} is provided to the first antenna 124-1 via the first directional coupler 122-1 to radiate the first transmit signal V_{TX1} into free space for wireless transmission to one or more remote devices. The first directional coupler 122-1, in turn, couples out a portion of the first transmit signal V_{TX1} to generate a first feedback signal V_{FB1} for measurement and tuning purposes, as discussed in more detail further herein.

With reference to the second transmit chain, a second digital data signal D_{TX2} is provided to an input of the second DPD circuit 112-2. The second DPD circuit 112-2 applies predistortion to the second digital data signal D_{TX2} based on control signals from the measurement/tuning circuit 160 to generate a second predistorted digital signal D_{PX2}. The second DAC 114-2 may receive the second predistorted digital signal D_{PX2} directly or via one or more components, and convert the second predistorted digital signal D_{PX2} into a second predistorted analog signal V_{PX2}. As mentioned, one or more intervening components between the second DPD circuit 112-2 and the second DAC 114-2 may include a data scrambler, an error correction code (ECC) circuit, a modulator, and/or other circuit(s). The second mixer 116-2 mixes the second predistorted analog signal V_{PX2} with a second LO signal V_{LO2} generated by the second LO 120-2 (upconverts the second predistorted analog signal V_{PX2}) to generate a second RF signal V_{RF2}. It shall be understood that one or more filters may be associated with the second mixer 116-2 to substantially remove or suppress unwanted signal components from the second RF signal V_{RF2}.

The second DA 118-2 amplifies the second RF signal V_{RF2} to generate a second pre-amplified signal V_{DA2} based on control signals generated by the measurement/tuning circuit 160. The second PA 121-2 amplifies the second pre-amplified signal V_{DA2} based on control signals generated by the measurement/tuning circuit 160 to generate a second transmit signal V_{TX2}. The second transmit signal V_{TX2} is provided to the second antenna 124-2 via the second directional coupler 122-2 to radiate the second transmit signal V_{TX2} into free space for wireless transmission to one or more remote devices. The second directional coupler 122-2, in turn, couples out a portion of the second transmit signal V_{TX2} to generate a second feedback signal V_{FB2} for measurement and tuning purposes, as discussed in more detail further herein.

As discussed, the feedback receiver is for tuning the first and second transmit chains, including tuning the predistortion applied by the first and second DPD circuits 112-1 and 112-2, the gains of the first and second DAs 118-1 and 118-2, and the gains of the first and second PAs 121-1 and 121-2. For example, when the first transmit chain is to be tuned based on the first transmit signal V_{TX1}, the measurement/tuning circuit 160 sets the switching devices SW1 and SW5 in their closed states, and the switching devices SW2, SW3, SW4, and SW6 in their open states. Additionally, the measurement/tuning circuit 160 sets the switching device SW7, which may be implemented as a single pole double throw (SPDT) switch, such that it couples the switching device SW5 to the input of the FB RX input stage 150, and decouples the switching device SW6 from the input of the FB RX input stage 150.

In this configuration, the first feedback signal V_{FB1} is provided to the input of the FB RX input stage 150 as input feedback signal V_{FBI} via the switching devices SW5 and SW7. As discussed further herein, the FB RX input stage 150 may provide a desired passband for the input feedback signal V_{FBI}, a desired impedance matching at the input of the LNA 152, programmable signal attenuation, and third harmonic rejection based on control signals generated by the measurement/tuning circuit 160. Accordingly, the FB RX input stage 150 produces an output feedback signal V_{FBO} based on the input feedback signal V_{FBI}. The LNA 152 amplifies the output feedback signal V_{FBO} to generate an amplified feedback signal V_{FBA}. The mixer 156 mixes the amplified feedback signal V_{FBA} with the first LO signal V_{LO1} received from the first LO 120-1 via the closed switching device SW1 (down converts the amplified feedback signal V_{FBA}) to generate a baseband feedback signal V_{FB}. The ADC 158 converts the baseband feedback signal V_{FB} into a digital feedback signal D_{FB}. The measurement/tuning circuit 160 tunes the first transmit chain based on the digital feedback signal D_{FB}.

For example, the measurement/tuning circuit 160 configures the FB RX input stage 150 to provide desired passband and impedance match to efficiently couple the first feedback signal V_{FB}, to the input of the LNA 152 based on the frequency of the input feedback signal V_{FBI} (same as the frequency of the first transmit signal V_{TX1} and the first feedback signal V_{FB1}). Depending on the expected power level of the first transmit signal V_{TX1}, the measurement/tuning circuit 160 may also configure the FB RX input stage 150 to provide no or some signal attenuation. Additionally, based on the relationship between the frequencies of the first transmit signal V_{TX1} and the second transmit signal V_{TX2} in, for example, ULCA mode of operation, the measurement/tuning circuit 160 configures the FB RX input stage 150 to provide third harmonic suppression filtering, as discussed in more detail further herein.

The measurement/tuning circuit 160 processes the digital feedback signal D_{FB} to measure distortion present in the first transmit signal V_{TX1}, and controls/tunes the first DPD circuit 112-1 to apply predistortion to the first digital data signal D_{TX1} so as to reduce the distortion in the first transmit signal V_{TX1}. The measurement/tuning circuit 160 also processes the digital feedback signal D_{FB} to determine the power level of the first transmit signal V_{TX1} to control/tune the gain of the first DA 118-1 and/or the first PA 121-1.

Alternatively, or in addition to, the first transmit chain may be tuned based on the first pre-amplified signal V_{DA1}. In this regard, the measurement/tuning circuit 160 sets the switching devices SW1 and SW3 in their closed states, and the switching devices SW2, SW4, SW5, and SW6 in their open states. As switching devices SW5 and SW6 are open, the measurement/tuning circuit 160 may set the switching device SW7 in any configuration, although setting it towards the first transmit chain may be better to reduce signal leakage from the second transmit chain into the FB RX input stage 150. In accordance with this measurement, the measurement/tuning circuit 160 processes the digital feedback signal D_{FB} to determine the power level of the first pre-amplified signal V_{DA1} to control/tune the gain of the first DA 118-1.

The tuning of the second transmit chain may operate in a similar manner. For example, when the second transmit chain is to be tuned based on the second transmit signal V_{TX2}, the measurement/tuning circuit 160 sets the switching devices SW2 and SW6 in their closed states, and the switching devices SW1, SW3, SW4, and SW5 in their open states. Additionally, the measurement/tuning circuit 160 sets the switching device SW7 such that it couples the switching device SW6 to the input of the FB RX input stage 150, and decouples the switching device SW5 from the input of the FB RX input stage 150.

In this configuration, the second feedback signal V_{FB2} is provided to the input of the FB RX input stage 150 as input feedback signal V_{FBI} via the switching devices SW6 and SW7. As discussed, the FB RX input stage 150 may provide a desired passband and impedance matching to efficiently couple the second feedback signal V_{FB2} to the input of the LNA 152, programmable signal attenuation, and third harmonic rejection based on control signals generated by the measurement/tuning circuit 160. Accordingly, the FB RX input stage 150 produces an output feedback signal V_{FBO} based on the input feedback signal V_{FBI}. The LNA 152 amplifies the output feedback signal V_{FBO} to generate an amplified feedback signal V_{FBA}. The mixer 156 mixes the amplified feedback signal V_{FBA} with the second LO signal V_{LO2} received from the second LO 120-2 via the closed switching device SW2 (down converts the amplified feedback signal V_{FBA}) to generate a baseband feedback signal V_{FB}. The ADC 158 converts the baseband feedback signal V_{FB} into a digital feedback signal D_{FB}. The measurement/tuning circuit 160 tunes the second transmit chain based on the digital feedback signal D_{FB}.

For example, the measurement/tuning circuit 160 configures the FB RX input stage 150 to provide a desired passband and impedance match to efficiently couple the second feedback signal V_{FB2} to the input of the LNA 152 based on the frequency of the input feedback signal V_{FBI} (same as the frequency of the second transmit signal V_{TX2} and the second feedback signal V_{FB2}). Depending on the expected power level of the second transmit signal V_{TX2}, the measurement/tuning circuit 160 may configure the FB RX input stage 150 to provide no or some signal attenuation. Additionally, based on the relationship between the frequencies of the second transmit signal V_{TX2} and the first transmit signal V_{TX1} in, for example, ULCA mode of operation, the measurement/tuning circuit 160 may provide third harmonic suppression filtering.

The measurement/tuning circuit 160 processes the digital feedback signal D_{FB} to measure distortion present in the second transmit signal V_{TX2}, and controls/tunes the second DPD circuit 112-2 to apply predistortion to the second digital data signal D_{TX2} so as to reduce the distortion in the second transmit signal V_{TX2}. The measurement/tuning circuit 160 also processes the digital feedback signal D_{FB} to determine the power level of the second transmit signal V_{TX2} to control/tune the gain of the second DA 118-2 and/or the second PA 121-2.

Alternatively, or in addition to, the second transmit chain may be tuned based on the second pre-amplified signal V_{DA2}. In this regard, the measurement/tuning circuit 160 sets the switching devices SW2 and SW4 in their closed states, and the switching devices SW1, SW3, SW5, and SW6 in their open states. As switching devices SW5 and SW6 are open, the measurement/tuning circuit 160 may set the switching device SW7 in any configuration, although setting it towards the second transmit chain may be better to reduce signal leakage from the first transmit chain into the FB RX input stage 150. In accordance with this measurement, the measurement/tuning circuit 160 processes the digital feedback signal D_{FB} to determine the power level of the second pre-amplified signal V_{DA2} to control/tune the gain of the second DA 118-2.

With regard to third harmonic suppression filtering of the FB RX input stage 150, this may be needed when one of the transmit chain is transmitting a signal with a frequency at or near three (3) times the frequency of the other transmit chain. For example, the first transmit signal V_{TX1} may have a first carrier with a frequency ƒ₁, and the second transmit signal V_{TX2} may have a second carrier with a frequency ƒ₂, where ƒ₂ is three (3) times ƒ₁. If the feedback receiver is measuring the first transmit chain with switching devices SW1 and SW5 is their closed states (and the switching devices SW2-SW4 and SW6 in their open states), and switching device SW7 set to route the first feedback signal V_{FB1} to the input of the FB RX input stage 150, the input feedback voltage V_{FBI} may include the first feedback signal V_{FB1}. However, the input feedback voltage V_{FBI} may also include a portion of the second transmit signal V_{TX2} due to antenna-to-antenna leakage and/or leakage via coupler 122-2, and switching devices SW6 and SW7.

The mixer 156 may downconvert the first transmit signal component of the amplified feedback signal V_{FBA} to a first baseband frequency ƒ_{BB1} substantially equal to a difference between the frequency ƒ₁ of the first transmit signal V_{TX1} and the frequency ƒ₀ of the first LO signal V_{LO1} (e.g., ƒ_{BB1}=ƒ₁-ƒ₀=Δƒ), and downconvert the leaked second transmit signal component of the amplified feedback signal V_{FBA} to a second baseband frequency ƒ_{BB2} substantially equal to a difference between the frequency ƒ₂ of the second transmit signal V_{TX2} and the third harmonic frequency 3ƒ₀ of the first LO signal V_{LO1} (e.g., ƒ_{BB2}=ƒ₂-3ƒ₀=3ƒ₁−3ƒ₀=3Δƒ). Thus, the difference between the baseband frequencies of the signal being measured and the leaked signal is 2Δƒ. The frequency difference 2Δƒ may be sufficiently small that the leaked signal interferes with and reduces the signal-to-noise ratio (SNR) of the measured signal, as well as increases the noise/distortion floor in the vicinity of the target baseband signal ƒ_{BB1}. As a result, tuning the first transmit chain by the measurement/tuning circuit 160 may be corrupted due to the reduced SNR of the measured signal and increased noise/distortion floor near ƒ_{BB1}. This is further explained with reference to FIGS. 1B and 1C. Although third harmonic suppression filtering is used herein as an example, it shall be understood that the FB RX input stage 150 may perform other harmonic filtering to reduce interference with the feedback receiver's measurement of a particular transmit chain.

FIG. 1B illustrates a graph depicting an example frequency spectrum of first and second transmit signals V_{TX1} and V_{TX2} of the transmitter system 100 in accordance with another aspect of the disclosure. The horizontal axis represents frequency ƒ, and the vertical axis represents power in decibel-milliwatt (dBm). The graph identifies a lower frequency band BAND1 depicted as a lighter-shaded frequency section, and a higher frequency band BAND2 depicted as a darker-shaded frequency section. For example, considering frequency bands reserved for New Radio, 5^{th} Generation developed by the 3^{rd} Generation Partnership Project (3GPP), the lower frequency band BAND1 may extend from 0.6 to 2.4 gigaHertz (GHz), and the higher frequency band BAND2 may extend from 2.4 GHz to 7.2 GHz.

The graph depicts the first transmit signal V_{TX1} with a bandwidth BW1 and a center frequency ƒ₀ within BAND1. In this example, the feedback receiver is a direct-conversion system, where the first transmit signal V_{TX1} is down converted to direct current (DC), and the frequency of the first LO signal V_{LO1} is also at ƒ₀. It shall be understood that the feedback receiver need not be implemented as a direct-conversion system. The second transmit signal V_{TX2} has a bandwidth BW2 with a center frequency 3ƒ₀ within BAND2, where 3ƒ₀ is the third harmonic of the first LO signal V_{LO1}. During measurement of the first transmit chain, the first PA 121-1 may be operated in a relatively low power or gain mode. Simultaneously, the second transmit chain may be operated in transmission mode, where the second PA 121-2 is operated in a relatively high power or gain mode. As a result, the power of the leaked second transmit signal V_{TX2} may be comparable power-wise to the power of the first feedback signal V_{FB1} in the input feedback signal V_{FBI}. As discussed above, the down conversion of the amplified feedback signal V_{FBA} by the mixer 156 may result in baseband signals, derived from the first and second transmit signals V_{TX1} and V_{TX2}, that interfere with each other, and adversely impact the SNR and the noise/distortion floor near the vicinity of the measured signal associated with the first transmit chain. This is further explained with reference to FIG. 1C.

FIG. 1C illustrates a graph depicting an example frequency spectrum of the feedback signal V_{FB} or D_{FB} of the transmitter system 100 in accordance with another aspect of the disclosure. Similarly, the horizontal axis represents frequency ƒ, and the vertical axis represents the power of the baseband signals V_{FB} or D_{FB} associated with the first transmit signal V_{TX1} and the leaked second transmit signal V_{TX2}. As the center frequency ƒ₀ of the first transmit signal V_{T}x and the center frequency 3 ƒ₀ of the leaked second transmit signal V_{TX2} are a factor of three (3) apart, the first LO signal V_{LO1} and its third harmonic frequency cause their respective down-converted baseband signals ƒ_{BB1} and ƒ_{BB2} to be centered at DC and overlap each other. Due to the overlap in frequencies of the baseband signals ƒ_{BB1} and ƒ_{BB2}, the baseband signal associated with the leaked second transmit signal V_{TX2} interferes with the baseband signal associated with the measured first transmit signal V_{TX1}, which has the adverse effect of reducing the SNR of the measured signal and increasing the noise/distortion floor in the vicinity of the measured first transmit signal V_{TX1}, which may cause erroneous tuning of the first transmit chain. Accordingly, third harmonic suppression filtering in the FB RX input stage 150 may be desired to reduce the power level of the leaked signal so that it does not adversely affect the measured signal for tuning purposes. After the first transmit chain is measured and tuned, the transmitter system 100 may be configured for carrier aggregation (CA) operation, where both transmit chains (or more) are used to cumulatively transmit data to one or more remote wireless devices.

FIG. 1D illustrates a graph depicting an example frequency spectrum of first and second transmit signals V_{TX1} and V_{TX2} of the transmitter system 100 in accordance with another aspect of the disclosure. The graph of FIG. 1D is similar to that FIG. 1B. It shall be understood that the center frequency of the second transmit signal V_{TX2} need not be exactly three (3) times the center frequency of the first transmit signal V_{TX1}, as in the example of FIG. 1B. But rather that the down-converted baseband signal ƒ_{BB2} of the leaked second transmit signal V_{TX2} due to the third harmonic 3ƒ₀ of the first LO signal V_{LO1} is sufficiently close to the down-converted baseband signal ƒ_{BB1} of the first transmit signal V_{TX1} being measured by the feedback receiver. For instance, in the example of FIG. 1D, the center frequency of the second transmit signal V_{TX2} is offset in frequency from the third harmonic 3ƒ₀ by A. Yet, as shown in FIG. 1E, the down-converted baseband signal ƒ_{BB2} of the leaked second transmit signal V_{TX2} overlaps with the down-converted baseband signal ƒ_{BB1} of the first transmit signal V_{TX1}; thereby, producing adverse SNR and noise/distortion floor effects.

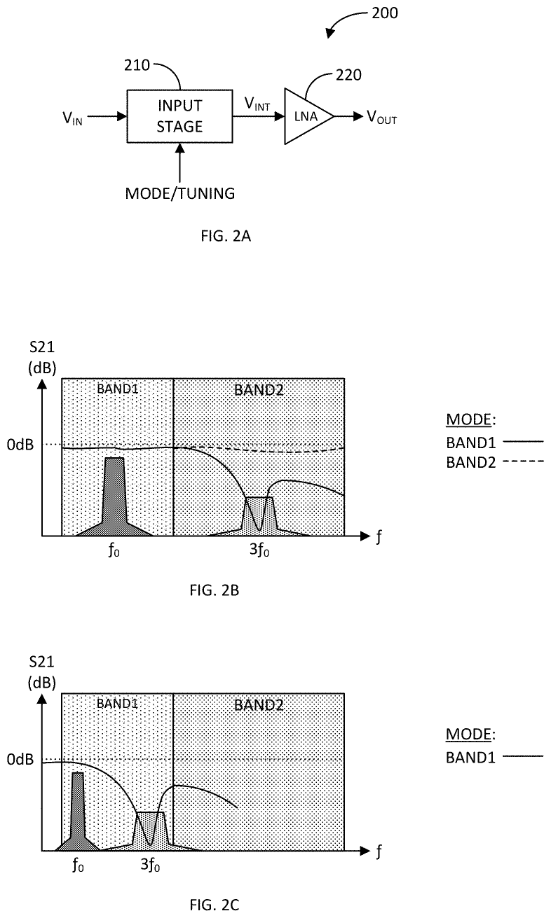

FIG. 2A illustrates a block diagram of an example receiver 200 in accordance with another aspect of the disclosure. The receiver 200 includes an input stage 210 and a low noise amplifier (LNA) 220. For example, the input stage 210 and LNA 220 may correspond to the FB RX input stage 150 and LNA 152 of the transmitter system 100, respectively. However, it shall be understood that the receiver 200 need not be implemented as a feedback receiver, but may be used in other signal receiving applications.

In this example, the input stage 210 includes a first input configured to receive an input signal V_{IN}. The input signal V_{IN} may include a first signal, such as the first feedback signal V_{FB1}, and a second signal, such as the leaked second transmit signal V_{TX2} of transmitter system 100. The input stage 210 may include a second input configured to receive a mode/tuning signal to specify one of two modes of operations, and tune parameters of the input stage 210 to achieve a desired S21 and S11 frequency response, and third harmonic suppression filtering. The mode/tuning signal may be generated by the measurement/tuning circuit 160. For example, the first mode of operation may be to measure the first transmit signal V_{TX1} for the purpose of tuning the first transmit chain of transmitter system 100. The second mode of operation may be to measure the second transmit signal V_{TX2} for the purpose of tuning the second transmit chain of the transmitter system 100. In certain examples (e.g., where the LNA 220 is not used as a part of a feedback receiver), other modes of operation may exist for tuning where, for example, the input stage 210 is tuned for a particular band of a signal being received.

Accordingly, the input stage 210 is configured to provide a first passband (e.g., a 3 decibel (dB) passband) for the first signal across a first frequency band and a notch to substantially reject a second signal within the first or a second frequency band in accordance with the first mode of operation to generate an intermediate signal V_{INT}. The LNA 220 amplifies the intermediate signal V_{INT} to generate an output signal V_{OUT}. The mode/tuning signal configures the input stage 210 in accordance with the first mode of operation, and tunes parameters of the input stage 210 to achieve the first passband and the notch as described. With reference to FIG. 1B, the first frequency band may be BAND1 (e.g., 0.6 to 2.4 GHz) within which the center frequency ƒ₀ of the first signal lies. The second frequency band may be BAND2 (e.g., 2.4 GHz to 7.2 GHz) within which the center frequency 3ƒ₀ of the leaked second signal lies. As the frequency 3ƒ₀ of the leaked second signal may be three (3) times the frequency ƒ₀ of the first signal, third harmonic suppression filtering is desired to reduce the power of the leaked second signal so as not to significantly affect the SNR and noise/distortion floor of the first signal. The notch to reject the second signal performs the third harmonic suppression filtering.

The input stage 210 is also configured to provide a second passband (e.g., a 3 dB passband) for the second signal across the second frequency band in accordance with a second mode of operation to generate the intermediate signal V_{INT}. Similarly, the LNA 220 amplifies the intermediate signal V_{INT} to generate the output signal V_{OUT}. The mode/tuning signal configures the input stage 210 in accordance with the second mode of operation, and tunes parameters of the input stage 210 to achieve the second passband. Again, with reference to FIG. 1B, the second frequency band may be BAND2 (e.g., 2.4 GHz to 7.2 GHz) within which the frequency 3ƒ₀ of the second signal lies. As, in this example, the third harmonic of the frequency 3ƒ₀ of the second signal is above the second frequency band BAND2, and the transmitter system 100 does not transmit signals higher in frequency than the second frequency band BAND2, there may not be a need to provide third harmonic suppression filtering when measuring the second transmit chain in accordance with the second mode of operation. This is further explained with reference to FIG. 2B.

FIG. 2B illustrates a graph depicting example S21 frequency response of the input stage 210 of the receiver 200 in accordance with another aspect of the disclosure. The graph is similar to graph depicted in FIG. 1B, where the horizontal axis represents frequency ƒ, and in this case, the vertical axis represents the S21 frequency response of the input stage 210 for both modes of operations. In this example, the graph depicts the S21 frequency response of the input stage 210 as a solid line for the first or BAND1 mode of operation. The graph depicts the S21 frequency response of the input stage 210 as a dashed line for the second or BAND2 mode of operation. The dotted line represented 0 dB insertion loss associated with the S21 frequency response of the input stage 210.

According to the BAND1 mode of operation, the input stage 210 provides a passband (e.g., a 3 dB passband) for the first signal having a carrier at frequency ƒ₀ within the BAND1 frequency band, and a notch to substantially reject the second signal with a carrier at frequency 3ƒ₀ within the BAND2 frequency band. As the notch is situated at frequency 3ƒ₀, the notch substantially rejects the second signal to provide third harmonic suppression filtering to reduce adverse effects on the SNR and noise/distortion floor of the first signal. The first signal is amplified by the LNA 220, and subsequently down converted and processed in accordance with the particular application of the receiver 200. According to the BAND2 mode of operation, the input stage 210 provides a passband (e.g., a 3 dB passband) for the second signal having a carrier at frequency 3ƒ₀ within the BAND2 frequency band. As previously discussed, there may not be a need for third harmonic suppression in the BAND2 mode of operation because the transmitter system 100 may not include a transmit chain generates a transmit signal with frequency three (3) times higher than the lowest frequency of BAND2. In this example, the first frequency band BAND1 does not overlap with the second frequency band BAND2.

FIG. 2C illustrates a graph depicting another example S21 frequency response of the input stage 210 of the receiver 200 in accordance with another aspect of the disclosure. As previously discussed, an example of BAND1 frequency band extends from 0.6 to 2.4 GHz. For some frequencies of the BAND1 frequency band, the third harmonic still lies within the BAND1 frequency band. For example, if the carrier is at a frequency ƒ₀ of the first signal is between 0.6 to 0.8 GHz, the third harmonic 3ƒ₀ is between 1.8 to 2.4 GHz, which also lies within the BAND1 frequency band. Thus, in the examples of FIGS. 2B-2C, the frequency range for the notch is between 1.8 to 7.2 GHz. The second transmit chain may be transmitting a second signal within BAND1 frequency band, and be in the vicinity of three (3) times the frequency ƒ₀ of the first signal, where third harmonic suppression may be desired. Thus, the example of FIG. 2C illustrates the S21 of the frequency response of the input stage 210 including a 3 dB passband for the first signal with a carrier at ƒ₀ and a notch in the vicinity or substantially three (3) times higher 3ƒ₀ to suppress the second transmit signal to reduce adverse effects on the SNR and noise/distortion floor of the first signal.

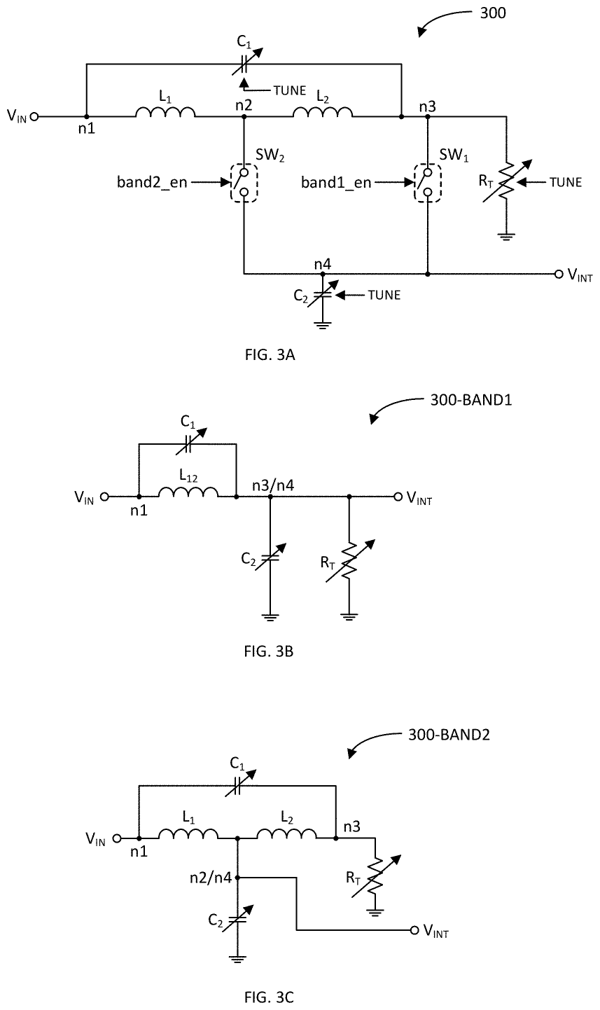

FIG. 3A illustrates a schematic diagram of an example receiver input stage 300 in accordance with another aspect of the disclosure. The input stage 300 may be an example implementation of any of the input stages 150 and 210 previously discussed. In particular, the input stage 300 includes a first inductor L₁, a second inductor L₂, a first capacitor C₁, a second capacitor C₂, a termination resistor R_{T}, a first switching device SW₁, and a second switching device SW₂.

More specifically, the first inductor L₁ is coupled between a first node n1 and a second node n2. The first node n1 may serve as the input of the input stage 300 to receive an input signal V_{IN}. The second inductor L₂ is coupled between the second node n2 and a third node n3. The first capacitor C₁, which may be variable or programmable based on a tuning signal (e.g., generated by the measurement/tuning circuit 160), is coupled between the first node n1 and the third node n3. The termination resistor R_{T}, which may also be variable or programmable based on a tuning signal (e.g., generated by the measurement/tuning circuit 160), is coupled between the third node n3 and ground (or some reference potential rail, which may be at alternating current (AC) ground). The first switching device SW₁, whose open/closed state is controlled by a band1_en mode signal (e.g., generated by the measurement/tuning circuit 160), is coupled between the third node n3 and a fourth node n4. Similarly, the second switching device SW₂, whose open/closed state is controlled by a band2_en mode signal (e.g., generated by the measurement/tuning circuit 160), is coupled between the second node n2 and the fourth node n4. The second capacitor C₂, which may be variable or programmable based on the tuning signal (e.g., generated by the measurement/tuning circuit 160), is coupled between the fourth node n4 and ground. The fourth node n4 may serve as the output of the input stage 300 to produce an intermediate signal V_{INT}. The output may be coupled to an input of an LNA, as previously discussed.

FIG. 3B illustrates a schematic diagram of an example equivalent circuit 300-BAND1 of the receiver input stage 300 in a first mode of operation in accordance with another aspect of the disclosure. In the first mode of operation, the input stage 300 is configured to provide a passband (e.g., 3 dB passband) across a lower frequency band (e.g., 0.6 to 2.4 GHz), and a notch at a frequency within the lower or a higher frequency band (e.g., 2.4 to 7.2 GHz).

With additional reference to FIG. 3A, in accordance with the first mode of operation, the band1_en mode signal is asserted, and the band2_en signal is deasserted. Responsively, the first switching device SW₁ is closed and the second switching device SW₂ is open. Thus, the equivalent circuit 300-BAND1 includes a resonance circuit including capacitor C₁ coupled in parallel with inductor L₁₂ between the input node n1 and an output node n3/n4, wherein the inductor L₁₂ includes the first and second inductors L₁ and L₂ coupled in series. The capacitor C₂ and termination resistor R_{T} is coupled in parallel between the output node n3/n4 and ground. The resonance circuit may be tuned, by tuning the capacitance of the capacitor C₁, which in conjunction with the cumulative inductances of the first and second inductors L₁ and L₂, produce a notch within the first frequency band (e.g., 0.6 to 2.4 GHz) or the second frequency band (e.g., 2.4 to 7.6 GHz) to perform third harmonic suppression filtering as previously discussed. Additionally, the inductor L₁₂ and capacitor C₂, in conjunction with the termination resistor R_{T}, operate as an L-match impedance matching circuit, which may be tuned by tuning the capacitance of capacitor C₂ to achieve the desired passband and impedance matching across at least a portion of the first frequency band (e.g., 0.6 to 2.4 GHz).

FIG. 3C illustrates a schematic diagram of an example equivalent circuit 300-BAND2 of the receiver input stage 300 in a second mode of operation in accordance with another aspect of the disclosure. In the second mode of operation, the input stage 300 is configured to provide a passband (e.g., 3 dB passband) across the higher frequency band (e.g., 2.4 to 7.2 GHz). As previously discussed, in this mode, there may not be a need to provide third harmonic suppression filtering.

With additional reference to FIG. 3A, in accordance with the second mode of operation, the band1_en mode signal is deasserted, and the band2_en signal is asserted. Responsively, the first switching device SW₁ is open and the second switching device SW₂ is closed. Thus, the equivalent circuit 300-BAND2 includes a bridge T-coil impedance matching circuit including capacitor C₁ coupled in parallel with the series inductors L₁ and L₂ between the first node n1 and the third node n3, the capacitor C₂ coupled between the output node n2/n4 (situated between the series inductors L₁ and L₂) and ground. The bridge T-coil impedance matching circuit, which has very good wideband impedance matching properties, may be tuned to provide a desired passband and impedance matching across the second frequency band (e.g., 2.4 to 7.2 GHz). The bridge T-coil impedance matching circuit may be tuned by tuning the capacitances of capacitors C₁ and C₂ and the resistance of termination resistor R_{T}. Typically, the bridge T-coil impedance provides mutual (electromagnetic) coupling between the first and second inductors L₁ and L₂. However, to reduce electromagnetic leakage to other nearby components, the first and second inductors L₁ and L₂ may be implemented so that the mutual coupling between them is substantially nil.

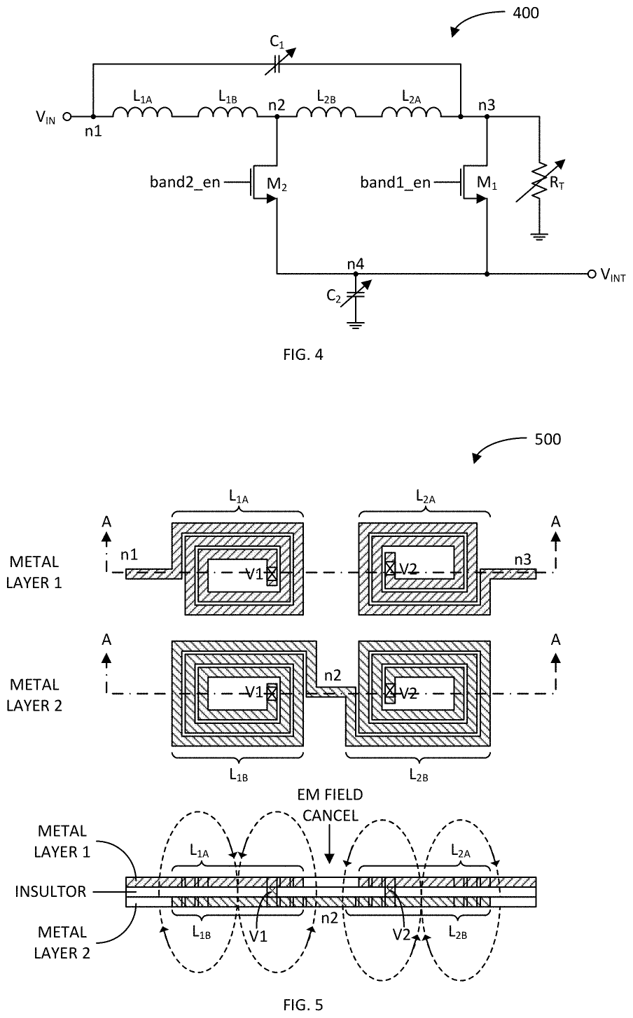

FIG. 4 illustrates a schematic diagram of another example receiver input stage 400 in accordance with another aspect of the disclosure. The input stage 400 may be another example of a more detailed implementation of the input stage 150 or 210. In particular, the input stage 400 includes a first inductor L_{1A}, a second inductor L_{1B}, a third inductor L_{2B}, a fourth inductor L_{2A}, a first capacitor C₁, a second capacitor C₂, a termination resistor R_{T}, a first field effect transistor (FET) M₁, and a second FET M₂.

More specifically, the first inductor L_{1A} and second inductor L_{1B} are coupled in series between a first node n1 and a second node n2. The first node n1 may serve as the input of the input stage 400 to receive an input signal V_{N}. The third inductor L_{2B} and the fourth inductor L_{2A} are coupled in series between the second node n2 and a third node n3. The first capacitor C₁, which may be variable or programmable based on a tuning signal (e.g., generated by the measurement/tuning circuit 160), is coupled between the first node n1 and the third node n3. The termination resistor R_{T}, which may also be variable or programmable based on a tuning signal (e.g., generated by the measurement/tuning circuit 160), is coupled between the third node n3 and ground.

The first FET M₁, whose on/off state is controlled by a band1_en mode signal (e.g., generated by the measurement/tuning circuit 160), is coupled between the third node n3 and a fourth node n4. Similarly, the second FET M₂, whose on/off state is controlled by a band2_en mode signal (e.g., generated by the measurement/tuning circuit 160), is coupled between the second node n2 and the fourth node n4. The first and second FETs M₁ and M₂ operate as switching devices, and may each be implemented as an n-channel metal oxide semiconductor (NMOS) FET, a p-channel metal oxide semiconductor (PMOS) FET, a transmission gate, a pass gate, or other electrically controllable switching device. The second capacitor C₂, which may be variable or programmable based on the tuning signal (e.g., generated by the measurement/tuning circuit 160), is coupled between the fourth node n4 and ground. The fourth node n4 may serve as the output of the input stage 400 to produce an intermediate signal V_{INT}. The output may be coupled to an input of an LNA, as previously discussed.

Similar to input stage 300, in accordance with a first mode of operation, the band1_en mode signal is asserted (e.g., at a logic high state), and the band2_en signal is deasserted (e.g., at a logic low state). Responsively, the first FET M₁ is turned on and the second FET M₂ is turned off. Thus, the input stage 400 forms a resonance circuit including capacitor C₁ coupled in parallel with the series inductors L_{1A}, L_{1B}, L_{2B}, and L_{2A} between the input node n1 and an output node n3/n4 to produce a notch at a tuned frequency within a first frequency band (e.g., 0.6 to 2.4 GHz) or a second frequency band (e.g., 2.4 to 7.2 GHz) for third harmonic suppression purposes. In this configuration, the series inductors L_{1A}, L_{1B}, L_{2B}, and L_{2A} are also coupled to the shunt capacitor C₂ to form an L-match impedance matching circuit to provide a desired passband and impedance matching across at least a portion of the first frequency band (e.g., 0.6 to 2.4 GHz). In accordance with a second mode of operation, the band1_en mode signal is deasserted (e.g., at a low logic state), and the band2_en signal is asserted (e.g., at a high logic state). Responsively, the first FET M₁ is off and the second FET M₂ is on. Thus, the input stage 400 forms a bridge T-coil impedance matching circuit including capacitor C₁ coupled in parallel with the series inductors L_{1A}, L_{1B}, L_{2B}, and L_{2A} between the input node n1 and the third node n3, the capacitor C₂ coupled between output node n2/n4 (situated between the series inductors L_{1B} and L_{2B}) and ground, to provide a desired passband and impedance matching across the second frequency band (e.g., 2.4 to 7.2 GHz).

FIG. 5 illustrates plan and cross-sectional views of an example inductive component 500 used in an example receiver input stage in accordance with another aspect of the disclosure. The inductive component 500 may be an example implementation of the inductors L_{1A}, L_{B}, L_{2B}, and L_{2A} of the receiver input stage 400. In this example, the inductive component 500 may be implemented in an integrated circuit (IC), such as a system on chip (SOC).

The top portion of FIG. 5 depicts a plan view of a first or upper metallization layer “1” of the IC upon which the inductors L_{1A} and L_{2A} are formed. The inductor L_{1A} is formed as a metallization winding in a clockwise direction as seen from above. The inductor L_{1A} includes a lead-in transmission line at node n1. The inductor L_{1A} terminates its clockwise winding at a metallized via hole V1. Similarly, the inductor L_{2A} is formed as a metallization winding in a counterclockwise direction as seen from above. The inductor L_{2A} begins its counterclockwise winding at a metallized via hole V2. The inductor L_{2A} includes a lead-out transmission line at node n3.

The middle portion of FIG. 5 depicts a plan view of a second or lower metallization layer “2” of the IC upon which the inductors L_{1B} and L_{2B} are formed. The inductor L_{1B} is formed as a metallization winding in a clockwise direction as seen from above, and vertically aligned with the inductor L_{1A}. The inductor LIB begins its clockwise winding at the metallized via hole V1, which electrically couples the inductors L_{1A} and L_{1B} in series, and includes a lead-out at node n2. The inductor L_{2B} includes shares a lead-in with the lead-out of inductor L_{1B} at node n2, and terminates its counterclockwise winding at the metallized via hole V2, which electrically couples the inductors L_{2B} and L_{2A} in series. The inductor L_{2B} is vertically aligned with the inductor L_{2A}. Thus, in this configuration, the inductors L_{1A}, L_{1B}, L_{2B}, and L_{2A} are coupled in series between nodes n1 and n3.

The lower portion of FIG. 5 depicts a cross-sectional view of the IC along line A-A, also depicted in the plan views in the top and middle portions of FIG. 5. The cross-sectional view also depicts an electrically insulating layer sandwiched between the upper metallization layer 1 and the lower metallization layer 2. The inductors L_{1A} and L_{1B} having clockwise windings and the inductors L_{2B} and L_{2A} having counterclockwise windings produce electromagnetic fields that substantially cancel along a boundary line symmetrically separating the inductors L_{1A}/L_{1B} from inductors L_{2B}/L_{2A}.

For example, as depicted, the clockwise currents along inductors L_{1A} and L_{1B} produce an electromagnetic field (shown as the left pair of dashed ellipticals) that points downward at the center of the inductors L_{1A} and L_{1B}, and upwards external to the inductors L_{1A} and L_{1B}. Conversely, the counterclockwise currents along inductors L_{2A} and L_{2B} produce an electromagnetic field (shown as the right pair of dashed ellipticals) that points upward at the center of the inductors L_{2A} and L_{2B}, and points downwards external to the inductors L₂a and L_{2B}. Thus, at node n2 (and along the boundary line symmetrically separating the inductors), the upward pointing electromagnetic field generated by inductors L_{1A} and L_{1B} substantially cancels out the downward pointing electromagnetic field generated by inductors L_{2A} and L_{2B}. This substantially eliminates mutual coupling between the inductors L_{1A}/L_{1B} and L_{2B}/L_{2A}, and substantially reduces the electromagnetic field leakage to other nearby components.

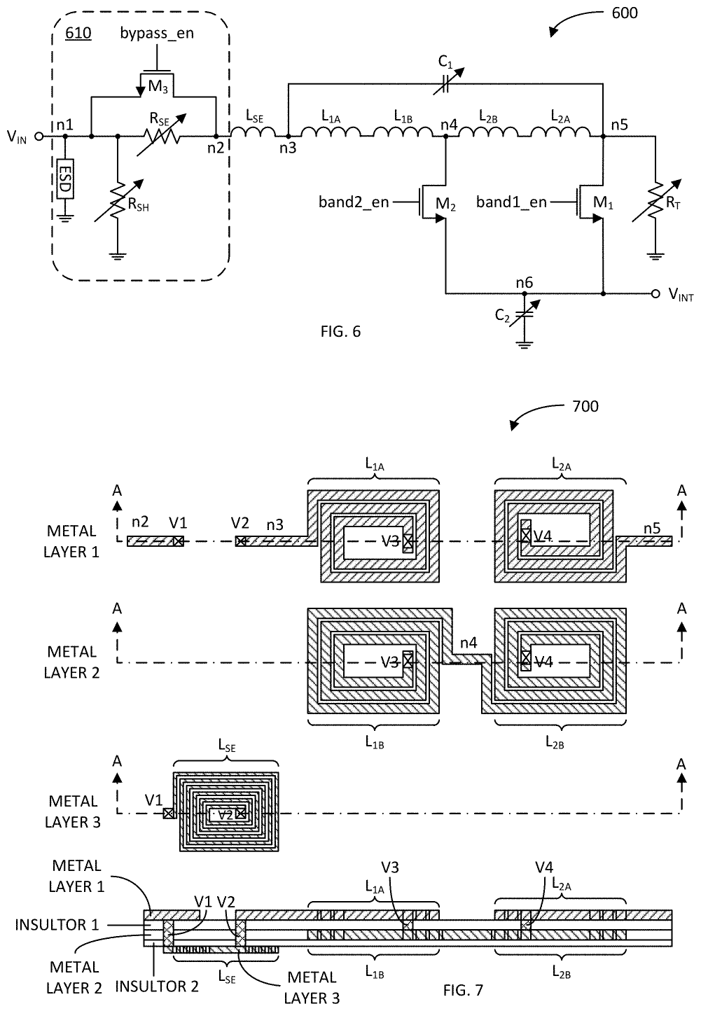

FIG. 6 illustrates a schematic diagram of another example receiver input stage 600 in accordance with another aspect of the disclosure. The input stage 600 may be another example of a more detailed implementation of the input stage 150 or 210. In particular, the input stage 600 includes an attenuator 610, a first inductor L_{SE}, a second inductor L_{1A}, a third inductor LIB, a fourth inductor L_{2B}, a fifth inductor L_{2A}, a first capacitor C₁, a second capacitor C₂, a termination resistor R_{T}, a first field effect transistor (FET) M₁, and a second FET M₂. The attenuator 610, in turn, includes a shunt resistor R_{SH}, a series resistor R_{SE}, and a third FET M₃. Although not necessarily part of the attenuator 610, the input stage 600 also includes an electrostatic discharge (ESD) device. It shall be understood that although a particular circuit arrangement for an attenuator is shown as an example, other circuit implementations for the attenuator are possible.

More specifically, the ESD device is coupled between a first node n1 and ground. The first node n1 may serve as the input of the input stage 600 to receive an input signal V_{IN}. The shunt resistor R_{SH} of the attenuator 610, which may be a variable resistor, is coupled between the first node n1 and ground. The series resistor R_{SE} of the attenuator 610, which may also be a variable resistor, is coupled between the first node n1 and a second node n2. Similarly, the FET M₃ is coupled in parallel with the series resistor R_{SE} between the first and second nodes n1 and n2, and includes a gate configured to receive a bypass_en signal from, for example, the measurement/tuning circuit 160. The tunability of the variable resistors R_{SH} and R_{SE} may also be controlled by the measurement/tuning circuit 160.

The first inductor L_{SE} is coupled between the second node n2 and a third node n3. The second inductor L_{1A} and third inductor LIB are coupled in series between the third node n3 and a fourth node n4. The fourth inductor L_{2B} and the fifth inductor L_{2A} are coupled in series between the fourth node n4 and a fifth node n5. The first capacitor C₁, which may be variable or programmable based on a tuning signal generated by, for example, the measurement/tuning circuit 160, is coupled between the third node n3 and the fifth node n5. The termination resistor R_{T}, which may also be variable or programmable based on a tuning signal generated by, for example, the measurement/tuning circuit 160, is coupled between the fifth node n5 and ground.

The first FET M₁, whose on/off state is controlled by a band1_en mode signal, is coupled between the fifth node n5 and a sixth node n6. Similarly, the second FET M₂, whose on/off state is controlled by a band2_en mode signal, is coupled between the fourth node n4 and the sixth node n6. The FETs M₁ and M₂, as well as FET M₃ of the attenuator 610, operate as switching devices, and may each be implemented as an NMOS FET, PMOS FET, a transmission gate, a pass gate, or other electrically controllable switching device. The second capacitor C₂, which may be variable or programmable based on the tuning signal generated by, for example, the measurement/tuning circuit 160, is coupled between the sixth node n6 and ground. The sixth node n6 may serve as the output of the input stage 600 to produce an intermediate signal V_{INT}. The output may be coupled to an input of an LNA, as previously discussed.

The attenuation operation of the attenuator 610 may be bypassed, for example, by the measurement/tuning circuit 160, by asserting the bypass_en signal (e.g., set to a logic high). In this manner, the input signal V_{IN} avoids the resistances of the shunt and series resistors R_{SH} and R_{SE} as it propagates from the first node n1 to the second node n2. If a particular attenuation of the input signal V_{IN} is desired, the bypass_en signal is deasserted (e.g., set to a logic low), and the resistances of the shunt and series resistors R_{SH} and R_{SE} are tuned, for example, in accordance with the following table:

| Attenuation | bypass_en | | | | |
|---|---|---|---|---|---|
| Level | signal | α | R_{SH}(Ω) | R_{SE}(Ω) | Z_{IN}(Ω) |
| 0 dB | 1 | N/A | N/A | N/A | 50 |
| 3 dB | 0 | 0.707 | 170.71 | 20.71 | 50 |
| 6 dB | 0 | 0.500 | 100.00 | 50.00 | 50 |
| 9 dB | 0 | 0.353 | 77.35 | 91.42 | 50 |
| 12 dB | 0 | 0.250 | 66.67 | 150.00 | 50 |
| 15 dB | 0 | 0.177 | 60.74 | 232.85 | 50 |

Where R_{SH}(Ω) and R_{SE}(Ω) may be set in accordance with the following equations if an input impedance of 50 Ohms for the attenuator 610 is to be set:

$${R}_{SH} = \frac{50 Ω}{1 - α} \qquad Eq . 1$$

$${R}_{SE} = 50 Ω ( \frac{1 - α}{α} ) \qquad Eq . 2$$

If, as previously discussed with reference to input stages 300 and 400, the circuit following the attenuator 610 is configured to provide good impedance matching or substantially 50Ω impedance across the first and second frequency bands in accordance with the first and second modes of operations, then changing the attenuation provided by the attenuator 610 does not significantly affect the S21 and S11 frequency response of the receiver input stage 600. The series inductor L_{SE} following the attenuator 610 may be provided to compensate for shunt capacitance associated with the ESD and parasitic in the attenuator 610.

Similar to input stages 300 and 400, in accordance with a first mode of operation, the band1_en mode signal is asserted (e.g., at a high logic state), and the band2_en signal is deasserted (e.g., at a low logic state). Responsively, the first FET M₁ is turned on and the second FET M₂ is turned off. Thus, the input stage 600 forms a resonance circuit including capacitor C₁ coupled in parallel with the series inductors L_{1A}, L_{1B}, L_{2B}, and L_{2A} between the third node n3 and an output node n5/n6 to produce a notch at a tuned frequency within a first frequency band (e.g., 0.6 to 2.4 GHz) or second frequency band (e.g., 2.4 to 7.2 GHz) for third harmonic suppression purposes. Also, the series inductors L_{1A}, L_{1B}, L_{2B}, and L_{2A} are coupled to the shunt capacitor C₂ to form an L-match impedance matching circuit to provide a desired passband and impedance matching across at least a portion of the first frequency band (e.g., 0.6 to 2.4 GHz). The capacitance of the first and second capacitors C₁ and C₂, and the resistance of the termination resistor R_{T} may be tuned by, for example, the measurement/tuning circuit 160 to achieve the desired passband, impedance matching, and notch frequency in accordance with the first mode of operation.

In accordance with a second mode of operation, the band1_en mode signal is deasserted (e.g., at a low logic state), and the band2_en signal is asserted (e.g., at a high logic state). Responsively, the first FET M₁ is turned off and the second FET M₂ is turned on. Thus, the input stage 600 forms a bridge T-coil impedance matching circuit including capacitor C₁ coupled in parallel with the series inductors L_{1A}, L_{1B}, L_{2B}, and L_{2A} between the third node n3 and the fifth node n5, the capacitor C₂ coupled between output node n4/n6 (situated between the series inductors L_{1B} and L_{2B}) and ground to provide a desired passband and impedance matching across the second frequency band (e.g., 2.4 to 7.2 GHz). The capacitance of the first and second capacitors C₁ and C₂, and the resistance of the termination resistor R_{T} may be tuned by, for example, the measurement/tuning circuit 160 to achieve the desired passband and impedance matching in accordance with the second mode of operation.

FIG. 7 illustrates plan and cross-sectional views of an example inductive component 700 used in an example receiver input stage in accordance with another aspect of the disclosure. The inductive component 700 may be an example implementation of the inductors L_{SE}, L_{1A}, L_{1B}, L_{2B}, and L_{2A} of the receiver input stage 600. In this example, the inductive component 700 may be implemented in an integrated circuit (IC), such as a system on chip (SOC).

The top portion of FIG. 7 depicts a plan view of an upper or top metallization layer “1” of the IC upon which the inductors L_{1A} and L_{2A} are formed. The inductor L_{1A} is formed as a metallization winding in a clockwise direction as seen from above. The inductor L_{1A} includes a lead-in transmission line at node n3 from a metallized via hole V2. The inductor L_{1A} terminates its clockwise winding at a metallized via hole V3. Similarly, the inductor L_{2A} is formed as a metallization winding in a counterclockwise direction as seen from above. The inductor L_{2A} begins its counterclockwise winding at a metallized via hole V4. The inductor L_{2A} includes a lead-out transmission line at node n5. The upper or top metallization layer “1” also includes a lead-in to metallized via hole V1 at node 2. As discussed below, the metallized via hole V1 electrically couples to inductor L_{SE}.

The second portion from the top of FIG. 7 depicts a plan view of another metallization layer “2” lower than metallization layer “1” of the IC upon which the inductors LIB and L_{2B} are formed. The inductor L_{1B} is formed as a metallization winding in a clockwise direction as seen from above, and vertically aligned with the inductor L_{1A}. The inductor LIB begins its clockwise winding at the metallized via hole V3, which electrically couples the inductors L_{1A} and L_{1B} in series, and includes a lead-out at node n4. The inductor L_{2B} shares a lead-in with the lead-out of inductor L_{1B} at node n4, and terminates its counterclockwise winding at the metallized via hole V4, which electrically couples the inductors L_{2B} and L_{2A} in series. The inductor L_{2B} is vertically aligned with the inductor L_{2A}. Thus, in this configuration, the inductors L_{1A}, L_{1B}, L_{2B}, and L_{2A} are coupled in series between nodes n3 and n5.

The third portion from the top of FIG. 7 depicts a plan view of yet another metallization layer “3” lower than metallization layer “2” of the IC upon which the inductor L_{SE} is formed. The inductor L_{SE} is formed as a metallization winding in a clockwise direction as seen from above. The inductor L_{SE} begins its clockwise winding at the metallized via hole V1, which electrically couples to the lead-in at node 2. The inductor L_{SE} terminates its clockwise winding at the metallized via hole V2, which electrically couples the inductors L_{SE} and L_{1A} in series. Thus, in this configuration, the inductors L_{SE}, L_{1A}, L_{1B}, L_{2B}, and L_{2A} are coupled in series between nodes n2 and n5. As the inductor L_{SE} is formed at the metallization layer “3”, which is lower than the metallization layers “1” and “2” upon which the inductors L_{1A}/L_{2A} and L_{1B}/L_{2B} are formed, the thickness of the metal forming inductor L_{SE} may be smaller than the thickness of the metal forming inductors L_{1A}/L_{2A} and L_{1B}/L_{2B}. Thus, inductor L_{SE} may have a lower quality factor (Q) than the inductors L_{1A}/L_{2A} and L_{1B}/L_{2B}. But, as discussed, the inductor L_{SE} serves to compensate for capacitance associated with the attenuator 610, and the lower Q of the inductor L_{SE} may not have significant impact on the S21 and S11 frequency response of the input stage 600.

The bottom portion of FIG. 7 depicts a cross-sectional view of the IC along line A-A, also depicted in the plan views in the top, second- and third-from-the top portions of FIG. 7. The cross-sectional view also depicts a first electrically insulating layer sandwiched between the upper metallization layer 1 and the middle metallization layer 2, and a second electrically-insulating layer sandwiched between the middle metallization layer 2 and the lower metallization layer 3. As discussed with reference to inductive component 500, the inductors L_{1A} and L_{1B} having clockwise windings and the inductors L_{2B} and L_{2A} having counterclockwise windings produce electromagnetic fields that substantially cancel along a symmetrical boundary line separating the inductors L_{1A}/L_{1B} from inductors L_{2B}/L_{2A}. This substantially eliminates mutual coupling between the inductors L_{1A}/L_{1B} and L_{2B}/L_{2A}, and substantially reduces the electromagnetic field leakage to other nearby components.

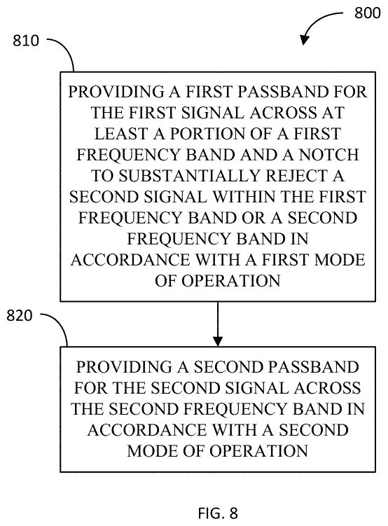

FIG. 8 illustrates a flow diagram of an example method 800 of processing first and second signals in accordance with another aspect of the disclosure. The method 800 includes providing a first passband for the first signal across at least a portion of a first frequency band and a notch to substantially reject a second signal within the first frequency band or a second frequency band in accordance with a first mode of operation (block 810). Examples of means for providing a first passband for the first signal across at least a portion of first frequency band and a notch to substantially reject a second signal within the first frequency band or a second frequency band in accordance with a first mode of operation include any one of the input stages 150, 210, 300, 400, 600 configured in the first or BAND1 mode of operation.

The method 800 further includes providing a second passband for the second signal across the second frequency band in accordance with a second mode of operation (block 820). Examples of means for providing a second passband for the second signal across the second frequency band in accordance with a second mode of operation include any one of the input stages 150, 210, 300, 400, 600 configured in the second or BAND2 mode of operation.

The following provides an overview of aspects of the present disclosure:

Aspect 1: A receiver, including: a low noise amplifier (LNA); and an input stage coupled to the LNA. The LNA includes a first inductor coupled between a first node and a second node; a second inductor coupled between the second node and a third node; a first variable capacitor coupled between the first node and the third node; a variable resistor coupled between the third node and a reference potential rail; a first switching device coupled between the second node and a fourth node; a second switching device coupled between the third node and the fourth node; and a second variable capacitor coupled between the fourth node and the reference potential rail.

Aspect 2: The receiver of aspect 1, wherein the fourth node of the input stage is coupled to an input of the LNA.

Aspect 3: The receiver of aspect 1 or 2, wherein the input stage further comprises a variable attenuator coupled to the first node.

Aspect 4: The receiver of any one of aspects 1-3, wherein the input stage is selectively coupled to at least two different transmit chains.

Aspect 5: The receiver of any one of aspects 1-3, wherein the first node is selectively coupled to outputs of power amplifiers (PAs) of different transmit chains, respectively.

Aspect 6: The receiver of any one of aspects 1-3, wherein the first node is selectively coupled to outputs of driver amplifiers (DAs) of different transmit chains, respectively.

Aspect 7: A receiver, including: a low noise amplifier (LNA); and an input stage coupled to the LNA, wherein the input stage is configured to provide a first passband for a first signal across at least a portion of a first frequency band and a notch to substantially reject a second signal within the first frequency band or a second frequency band in accordance with a first mode of operation, and a second passband for the second signal across the second frequency band in accordance with a second mode of operation.

Aspect 8: The receiver of aspect 7, wherein the first signal includes a carrier with a first frequency within the first frequency band, and wherein the notch is situated at a second frequency substantially three times the first frequency in accordance with the first mode of operation.

Aspect 9: The receiver of aspect 7 or 8, wherein the second signal has a carrier with a frequency within the second frequency band in accordance with the second mode of operation.

Aspect 10: The receiver of any one of aspects 7-9, wherein the first frequency band does not overlap with the second frequency band.

Aspect 11: The receiver of any one of aspects 7-10, wherein the input stage includes: a first inductor coupled between a first node and a second node; a second inductor coupled between the second node and a third node; a first capacitor coupled between the first node and the third node; a resistor coupled between the third node and ground; a first switching device coupled between the second node and a fourth node; a second switching device coupled between the third node and the fourth node; and a second capacitor coupled between the fourth node and ground.

Aspect 12: The receiver of aspect 11, wherein the first and second capacitors are variable capacitors, and the resistor is a variable resistor.

Aspect 13: The receiver of aspect 11 or 12, wherein the first switching device is open, and the second switching device is closed in accordance with the first mode of operation.

Aspect 14: The receiver of aspect 13, wherein a capacitance of the first capacitor and a cumulative inductance of the first and second inductors are configured to set a frequency of the notch in accordance with the first mode of operation.

Aspect 15: The receiver of aspect 13 or 14, wherein the first and second inductors and the second capacitor form an L-match impedance matching circuit for the first signal across the first frequency band in accordance with the first mode of operation.

Aspect 16: The receiver of any one of aspects 11-15, wherein the first switching device is closed, and the second switching device is open in accordance with the second mode of operation.

Aspect 17: The receiver of aspect 16, wherein the first and second inductors, and first and second capacitors form a bridge T-coil impedance matching circuit for the second signal across the second frequency band in accordance with the second mode of operation.

Aspect 18: The receiver of aspect 16 or 17, wherein a mutual coupling between the first and second inductors is substantially nil.

Aspect 19: The receiver of any one of aspects 11-18, wherein the first inductor is wound in a clockwise direction, and the second inductor is wound in a counterclockwise direction.

Aspect 20: The receiver of any one of aspects 7-19, wherein the input stage further includes an attenuator.

Aspect 21: The receiver of aspect 20, wherein the attenuator includes: a shunt resistor; and a series resistor.

Aspect 22: The receiver of aspect 21, wherein the attenuator further includes a switching device coupled in parallel with the series resistor.

Aspect 23: The receiver of any one of aspects 20-22, wherein the attenuator is coupled between first and second nodes, and wherein the input stage further includes: a first inductor coupled between the second node and a third node; a second inductor coupled between the third node and a fourth node; a third inductor coupled between the fourth node and a fifth node; a first capacitor coupled between the third node and the fifth node; a resistor coupled between the fifth node and ground; a first switching device coupled between the fourth node and a sixth node; a second switching device coupled between the fifth node and the sixth node; and a second capacitor coupled between the sixth node and ground.

Aspect 24: The receiver of any one of aspects 7-23, wherein the input stage is selectively coupled to: a first power amplifier (PA) to receive the first signal therefrom; and a second power amplifier (PA) to receive the second signal therefrom.

Aspect 25: The receiver of any one of aspects 7-24, wherein the input stage is selectively coupled to: a first pre-amplifier to receive the first input signal therefrom; and a second pre-amplifier to receive the second input signal therefrom.

Aspect 26: A method of processing first and second signals, including: providing a first passband for the first signal across at least a portion of a first frequency band and a notch to substantially reject a second signal within the first frequency band or a second frequency band in accordance with a first mode of operation; and providing a second passband for the second signal across the second frequency band in accordance with a second mode of operation.

Aspect 27: The method of aspect 26, wherein providing the first passband and the notch includes: coupling first and second inductors in parallel with a first capacitor between first and second nodes, wherein the first node is configured to receive the first and second signals, and wherein the second node is coupled to the LNA; coupling a second capacitor between the second node and ground; and coupling a resistor between the second node and ground.

Aspect 28: The method of aspect 26 or 27, wherein providing the second passband includes: coupling the first and second inductors in parallel with the first capacitor between first and second nodes, wherein the first node is configured to receive the second signal; coupling the resistor between the second node and ground; and coupling a second capacitor between a third node situated between the first and second inductors, and ground.

Aspect 29: A transmitter system, including: a first amplifier configured to generate a first signal; a second amplifier configured to generate a second signal; and a feedback receiver, including: a low noise amplifier (LNA); and an input stage coupled to the LNA, wherein the input stage is configured to provide a first passband for the first signal across at least a portion of a first frequency band and a notch to substantially reject the second signal within the first frequency band or a second frequency band in accordance with a first mode of operation, and a second passband for the second signal across the second frequency band in accordance with a second mode of operation.

Aspect 30: The transmitter system of aspect 29, wherein the input stage includes: a first inductor coupled between a first node and a second node; a second inductor coupled between the second node and a third node; a first capacitor coupled between the first node and the third node; a resistor coupled between the third node and ground; a first switching device coupled between the second node and a fourth node; a second switching device coupled between the third node and the fourth node; and a second capacitor coupled between the fourth node and ground.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure.

Thus, the disclosure is not intended to be limited to the examples described herein but is to be accorded the widest scope consistent with the principles and novel features disclosed herein.

What is claimed:

1. A receiver, comprising:
a low noise amplifier (LNA); and
an input stage coupled to the LNA, wherein the input stage comprises:
a first inductor coupled between a first node and a second node;
a second inductor coupled between the second node and a third node;
a first variable capacitor coupled between the first node and the third node;
a variable resistor coupled between the third node and a reference potential rail;
a first switching device coupled between the second node and a fourth node;
a second switching device coupled between the third node and the fourth node; and
a second variable capacitor coupled between the fourth node and the reference potential rail.

2. The receiver of claim 1, wherein the fourth node of the input stage is coupled to an input of the LNA.

3. The receiver of claim 1, wherein the input stage further comprises a variable attenuator coupled to the first node.

4. The receiver of claim 1, wherein the input stage is selectively coupled to at least two different transmit chains.

5. The receiver of claim 1, wherein the first node is selectively coupled to outputs of power amplifiers (PAs) of different transmit chains, respectively.

6. The receiver of claim 1, wherein the first node is selectively coupled to outputs of driver amplifiers (DAs) of different transmit chains, respectively.

7. A receiver, comprising:
a low noise amplifier (LNA); and
an input stage coupled to the LNA, wherein the input stage is configured to provide:
a first passband for a first signal across at least a portion of a first frequency band and a notch to substantially reject a second signal within the first frequency band or a second frequency band in accordance with a first mode of operation; and
a second passband for the second signal across the second frequency band in accordance with a second mode of operation.

8. The receiver of claim 7, wherein the first signal includes a carrier with a first frequency within the first frequency band, and wherein the notch is situated at a second frequency substantially three times the first frequency in accordance with the first mode of operation.

9. The receiver of claim 7, wherein the second signal has a carrier with a frequency within the second frequency band in accordance with the second mode of operation.

10. The receiver of claim 7, wherein the first frequency band does not overlap with the second frequency band.

11. The receiver of claim 7, wherein the input stage comprises:
a first inductor coupled between a first node and a second node;
a second inductor coupled between the second node and a third node;
a first capacitor coupled between the first node and the third node;
a resistor coupled between the third node and ground;
a first switching device coupled between the second node and a fourth node;
a second switching device coupled between the third node and the fourth node; and
a second capacitor coupled between the fourth node and ground.

12. The receiver of claim 11, wherein the first and second capacitors are variable capacitors, and the resistor is a variable resistor.

13. The receiver of claim 11, wherein the first switching device is open, and the second switching device is closed in accordance with the first mode of operation.

14. The receiver of claim 13, wherein a capacitance of the first capacitor and a cumulative inductance of the first and second inductors are configured to set a frequency of the notch in accordance with the first mode of operation.

15. The receiver of claim 13, wherein the first and second inductors and the second capacitor form an L-match impedance matching circuit for the first signal across the first frequency band in accordance with the first mode of operation.

16. The receiver of claim 11, wherein the first switching device is closed, and the second switching device is open in accordance with the second mode of operation.

17. The receiver of claim 16, wherein the first and second inductors, and first and second capacitors form a bridge T-coil impedance matching circuit for the second signal across the second frequency band in accordance with the second mode of operation.

18. The receiver of claim 17, wherein a mutual coupling between the first and second inductors is substantially nil.

19. The receiver of claim 11, wherein the first inductor is wound in a clockwise direction, and the second inductor is wound in a counterclockwise direction.

20. The receiver of claim 7, wherein the input stage further comprises an attenuator.

21. The receiver of claim 20, wherein the attenuator comprises:
a shunt resistor; and
a series resistor.

22. The receiver of claim 21, wherein the attenuator further comprises a switching device coupled in parallel with the series resistor.

23. The receiver of claim 20, wherein the attenuator is coupled between first and second nodes, and wherein the input stage further comprises:
a first inductor coupled between the second node and a third node;
a second inductor coupled between the third node and a fourth node;
a third inductor coupled between the fourth node and a fifth node;
a first capacitor coupled between the third node and the fifth node;
a resistor coupled between the fifth node and ground;
a first switching device coupled between the fourth node and a sixth node;
a second switching device coupled between the fifth node and the sixth node; and
a second capacitor coupled between the sixth node and ground.

24. The receiver of claim 7, wherein the input stage is selectively coupled to:
a first power amplifier (PA) to receive the first signal therefrom; and
a second power amplifier (PA) to receive the second signal therefrom.

25. The receiver of claim 7, wherein the input stage is selectively coupled to:
a first pre-amplifier to receive the first signal therefrom; and
a second pre-amplifier to receive the second signal therefrom.

26. A method of processing first and second signals, comprising:
providing a first passband for the first signal across at least a portion of a first frequency band and a notch to substantially reject a second signal within the first frequency band or a second frequency band in accordance with a first mode of operation; and
providing a second passband for the second signal across the second frequency band in accordance with a second mode of operation.

27. The method of claim 26, wherein providing the first passband and the notch comprises:
coupling first and second inductors in parallel with a first capacitor between first and second nodes, wherein the first node is configured to receive the first and second signals;
coupling a second capacitor between the second node and ground; and
coupling a resistor between the second node and ground.

28. The method of claim 27, wherein providing the second passband comprises:
coupling the first and second inductors in parallel with a first capacitor between first and second nodes, wherein the first node is configured to receive the second signal;
coupling the resistor between the second node and ground; and
coupling a second capacitor between a third node situated between the first and second inductors, and ground.

29. A transmitter system, comprising:
a first amplifier configured to generate a first signal;
a second amplifier configured to generate a second signal; and
a feedback receiver, comprising:
a low noise amplifier (LNA); and
an input stage coupled to the LNA, wherein the input stage is configured to provide a first passband for the first signal across at least a portion of a first frequency band and a notch to substantially reject the second signal within the first frequency band or a second frequency band in accordance with a first mode of operation, and a second passband for the second signal across the second frequency band in accordance with a second mode of operation.

30. The transmitter system of claim 29, wherein the input stage comprises:
a first inductor coupled between a first node and a second node;
a second inductor coupled between the second node and a third node;
a first capacitor coupled between the first node and the third node;
a resistor coupled between the third node and ground;
a first switching device coupled between the second node and a fourth node;
a second switching device coupled between the third node and the fourth node; and
a second capacitor coupled between the fourth node and ground.
